(19) United States
(12) Patent Application Publication
(10) Pub. No.: US 2025/0167090 A1
(43) Pub. Date: May 22, 2025

(54) SEMICONDUCTOR PACKAGE

(71) Applicant: SAMSUNG ELECTRONICS CO., LTD., Suwon-si (KR)

(72) Inventor: Duckgyu Kim, Suwon-si (KR)

(21) Appl. No.: 18/774,747

(22) Filed: Jul. 16, 2024

(30) Foreign Application Priority Data
Nov. 21, 2023 (KR) 10-2023-0162610

(51) Int. Cl. H01L 23/498; H01L 23/00

(52) U.S. Cl. CPC H01L 23/49827; H01L 23/49816; H01L 23/49822; H01L 24/05; H01L 24/13; H01L 2224/05548; H01L 2224/05571; H01L 2224/05573; H01L 2224/05624; H01L 2224/13024

(57) ABSTRACT

An example semiconductor package comprises a semiconductor chip that includes a chip pad on one surface of the semiconductor chip, a redistribution pattern electrically connected with the chip pad, an under-bump pattern on the redistribution pattern, and a first buffer polymer pattern between the under-bump pattern and the redistribution pattern. The under-bump pattern defines a main via at a center of the under-bump pattern and a subordinate via at an edge of the under-bump pattern. The first buffer polymer pattern is between the main via and the subordinate via. The main via and the subordinate via contact the redistribution pattern. The first buffer polymer pattern is isolated from the under-bump pattern and the redistribution pattern by the main via and the subordinate via.

### CROSS-REFERENCE TO RELATED APPLICATION

This application claims priority under 35 U.S.C § 119 to Korean Patent Application No. 10-2023-0162610 filed on Nov. 21, 2023, in the Korean Intellectual Property Office, the disclosure of which is hereby incorporated by reference in its entirety.

### BACKGROUND

A semiconductor package is provided to implement an integrated circuit chip to qualify for use in electronic products. A semiconductor package is typically configured such that a semiconductor chip is mounted on a printed circuit board and bonding wires or bumps are used to electrically connect the semiconductor chip to the printed circuit board. With the development of electronic industry, various studies have been conducted to improve reliability and durability of semiconductor packages.

### SUMMARY

The present disclosure relates to a semiconductor package with increased reliability.

The object of the present disclosure is not limited to the mentioned above, and other objects which have not been mentioned above will be clearly understood to those skilled in the art from the following description.

In some implementations, a semiconductor package may comprise: a semiconductor chip that includes a chip pad on one surface of the semiconductor chip; a redistribution pattern electrically connected to the chip pad; an under-bump pattern on the redistribution pattern; and a first buffer polymer pattern between the under-bump pattern and the redistribution pattern. The under-bump pattern may include a main via at a center of the under-bump pattern and a subordinate via at an edge of the under-bump pattern. The first buffer polymer pattern may be between the main via and the subordinate via. The main via and the subordinate via may be in contact with the redistribution pattern. The first buffer polymer pattern may be isolated by the main via and the subordinate via.

In some implementations, a semiconductor package may comprise: a semiconductor chip that includes a chip pad on one surface of the semiconductor chip; a redistribution pattern electrically connected to the chip pad; an under-bump pattern in contact with the redistribution pattern; and a connection terminal on the under-bump pattern. The under-bump pattern may include a main via at a center of the under-bump pattern and a subordinate via at an edge of the under-bump pattern. When viewed in plan, the subordinate via may have an annular shape that continuously extends to surround the main via. A horizontal width of the main via may be greater than a horizontal width of the subordinate via. A depth of the main via may be the same as or greater than a depth of the subordinate via.

In some implementations, a semiconductor package may comprise: a semiconductor chip that includes a chip pad on one surface of the semiconductor chip; a protection layer that covers the one surface of the semiconductor chip and exposes the chip pad; a first cover polymer pattern that covers the protection layer and exposes the chip pad; a redistribution pattern on the first cover polymer pattern and in contact with the chip pad; a second cover polymer pattern that covers the first cover polymer pattern and the redistribution pattern and exposes a portion of the redistribution pattern; an under-bump pattern on the second cover polymer pattern and the redistribution pattern and in contact with the redistribution pattern; a buffer polymer pattern between the under-bump pattern and the redistribution pattern; and a connection terminal on the under-bump pattern. The protection layer may include an inorganic dielectric material. Each of the redistribution pattern and the under-bump pattern may include a seed/barrier pattern and a conductive pattern on the seed/barrier pattern. The under-bump pattern may include a main via at a center of the under-bump pattern and a subordinate via at an edge of the under-bump pattern. The buffer polymer pattern may be between the main via and the subordinate via. The buffer polymer pattern may be spaced apart from the first cover polymer pattern and the second cover polymer pattern.

### BRIEF DESCRIPTION OF THE DRAWINGS

FIG. 1 illustrates a cross-sectional view showing an example of a semiconductor package.

FIG. 2A illustrates an example enlarged view showing section AA′ of FIG. 1.

FIG. 2B illustrates an example plan view showing a top surface of a redistribution pattern depicted in FIG. 2A.

FIG. 2C illustrates an example plan view showing a top surface of an under-bump pattern and a top surface of a buffer polymer pattern depicted in FIG. 2A.

FIG. 2D illustrates an example enlarged view showing section AA′ of FIG. 1.

FIG. 3 illustrates a cross-sectional view showing an example of a semiconductor package.

FIG. 4 illustrates an example enlarged view showing section BB′ of FIG. 3.

FIG. 5 illustrates a cross-sectional view showing an example of a semiconductor package.

FIG. 6 illustrates a cross-sectional view showing an example of a semiconductor package.

FIG. 7 illustrates a cross-sectional view showing an example of a semiconductor package.

FIGS. 8, 9A, 10A, and 11A illustrate example cross-sectional views showing a method of fabricating a semiconductor package.

FIGS. 9B, 10B, and 11B illustrate example plan views showing top surfaces taken along line CC′ of FIGS. 9A, 10A, and 11A, respectively.

FIGS. 12A, 13A, 14A, and 15A illustrate example cross-sectional views showing a method of fabricating a semiconductor package.

FIGS. 12B, 13B, 14B, and 15B illustrate example plan views showing a method of fabricating a semiconductor package.

### DETAILED DESCRIPTION

The following will now describe some implementations of the present disclosure in conjunction with the accompanying drawings.

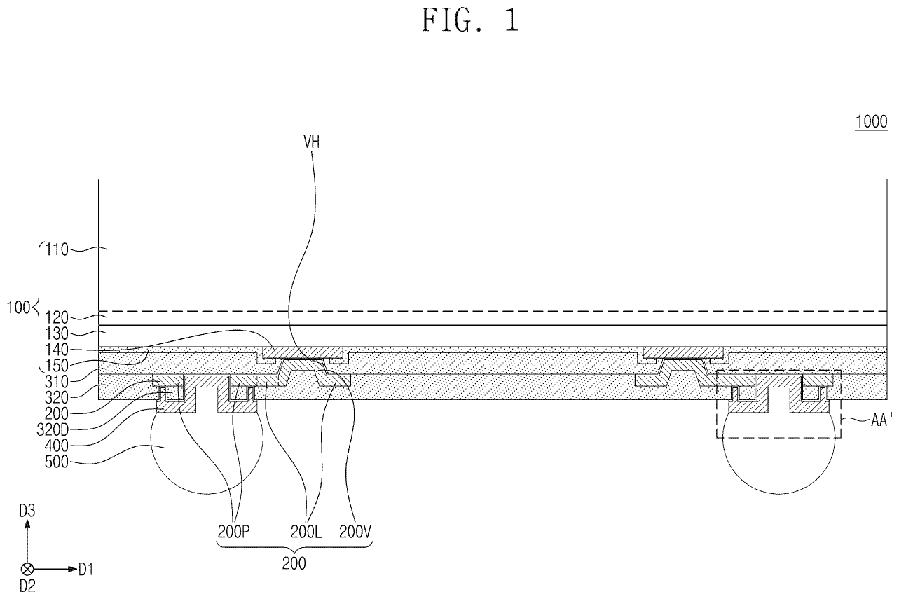

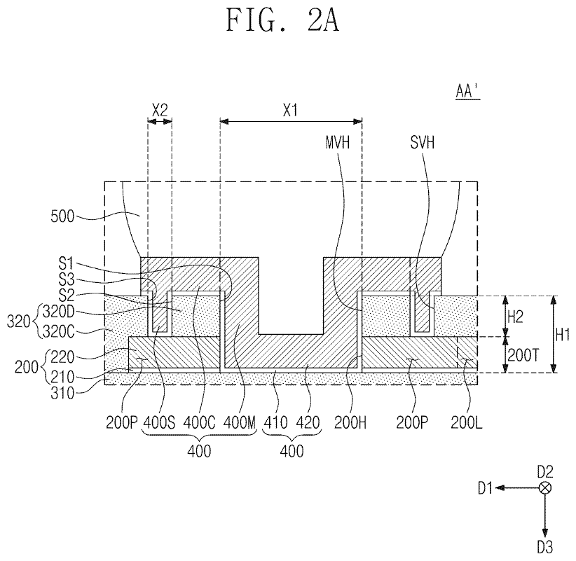

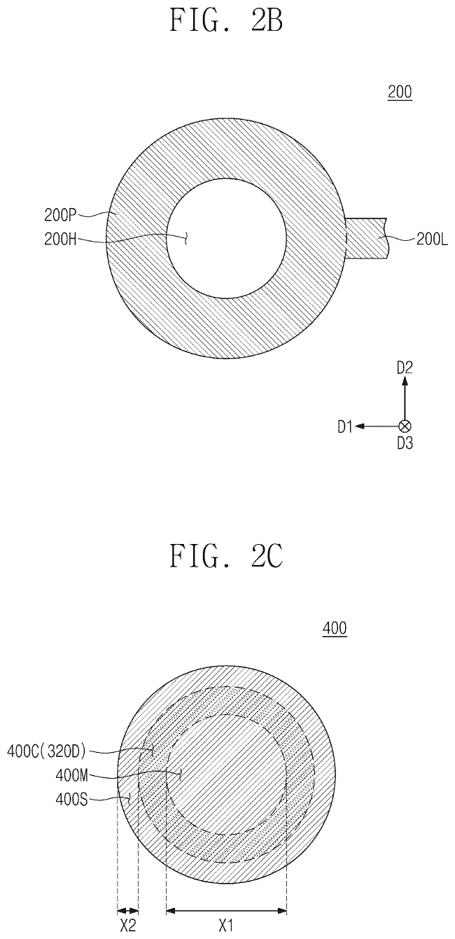

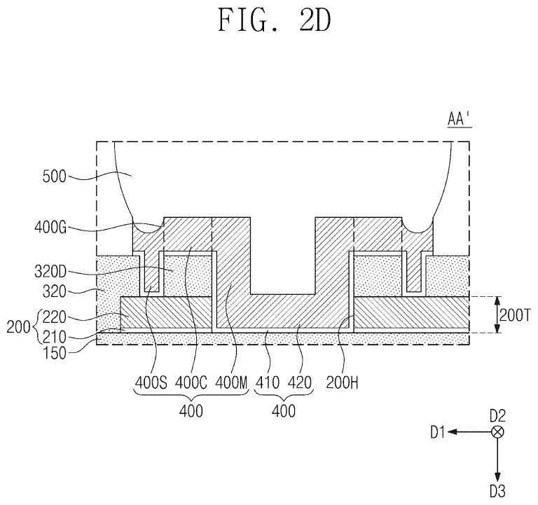

FIG. 1 illustrates a cross-sectional view showing an example of a semiconductor package. FIG. 2A illustrates an example enlarged view showing section AA′ of FIG. 1. In detail, FIG. 2A shows an enlarged overturned view showing section AA′ of FIG. 1. FIG. 2B illustrates an example plan view showing a top surface of a redistribution pattern depicted in FIG. 2A. FIG. 2C illustrates an example plan view showing a top surface of an under-bump pattern and a top surface of a buffer polymer pattern depicted in FIG. 2A. FIG. 2D illustrates an example enlarged view showing section AA′ of FIG. 1.

Referring to FIGS. 1 and 2A, a semiconductor package 1000 may include a semiconductor chip 100, a first polymer dielectric layer 310, a redistribution pattern 200, a second polymer dielectric layer 320, an under-bump pattern 400, and a connection terminal 500.

The semiconductor chip 100 may include a semiconductor substrate 110, a circuit layer 120, a wiring layer 130, a chip pad 140, and a protection layer 150. In this description, a first direction D1 may indicate one direction parallel to an exposed surface of the chip pad 140. A second direction D2 may indicate one direction orthogonal to the first direction D1 and parallel to the exposed surface of the chip pad 140. A third direction D3 may indicate a direction perpendicular to the exposed surface of the chip pad 140.

The semiconductor substrate 110 may include a semiconductor material, such as silicon, germanium, or silicon-germanium. The semiconductor substrate 110 may include a region on which an integrated circuit such as a transistor is disposed, and the circuit layer 120 may denote the region of the semiconductor substrate 110. The wiring layer 130 may include a dielectric layer and wiring lines that connect an integrated circuit in the dielectric layer to the chip pad 140. For example, the dielectric layer may include an inorganic dielectric material, such as silicon oxide (SiO₂). The wiring lines may include metal, such as aluminum or copper. The chip pad 140 may be disposed on one surface of the semiconductor chip 100. The chip pad 140 may be disposed on a top surface of the wiring layer 130 or on an uppermost part in the wiring layer 130. The chip pad 140 may include metal, such as aluminum.

The protection layer 150 may cover the wiring layer 130 and an edge of the chip pad 140. A top surface of the chip pad 140 may be exposed from the protection layer 150. The protection layer 150 may include an inorganic dielectric material, such as silicon nitride (Si₃N₄).

The first polymer dielectric layer 310 may be disposed on the protection layer 150. The first polymer dielectric layer 310 may include a different material from that of the protection layer 150. The first polymer dielectric layer 310 may include a photo-imageable polymer material. The first polymer dielectric layer 310 may include an organic material. The first polymer dielectric layer 310 may include one or more of photosensitive polyimide, polybenzoxazole, phenolic polymers, and benzocyclobutene polymers. The first polymer dielectric layer 310 may include a via hole VH that exposes the top surface of the chip pad 140.

The redistribution pattern 200 may be disposed on the first polymer dielectric layer 310 and the chip pad 140. The redistribution pattern 200 may be electrically connected to the chip pad 140. The redistribution pattern 200 may be in contact with the chip pad 140. According to some implementations, the redistribution pattern 200 may be connected through other electrical connection means to the chip pad 140, without being in contact with the chip pad 140.

The redistribution pattern 200 may include a first seed/barrier pattern 210 and a first conductive pattern 220. The first seed/barrier pattern 210 may include at least one selected from copper (Cu), titanium (Ti), tungsten (W), tantalum (Ta), and titanium nitride (TiN). The first seed/barrier pattern 210 may include, for example, copper/titanium. The first conductive pattern 220 may be disposed on the first seed/barrier pattern 210. The first conductive pattern 220 may include, for example, copper.

The redistribution pattern 200 may include a via part 200V, a line part 200L, and a pad part 200P. The via part 200V may fill at least a portion of the via hole VH of the first polymer dielectric layer 310. One end of the line part 200L may be connected to the via part 200V to extend onto a top surface of the first polymer dielectric layer 310. The line part 200L may extend in the first direction D1 or the second direction D2. Another end of the line part 200L may be connected to the pad part 200P. Referring to FIGS. 2A and 2B, the pad part 200P may have an annular shape or a ring shape whose center is hollow. The pad part 200P may include a pad hole 200H that exposes the top surface of the first polymer dielectric layer 310. The redistribution pattern 200 may have a thickness 200T of equal to or greater than about 10 μm.

The second polymer dielectric layer 320 may be disposed on the first polymer dielectric layer 310 and the redistribution pattern 200. For example, the second polymer dielectric layer 320 may cover the top surface of the first polymer dielectric layer 310, top and lateral surfaces of the via part 200V of the redistribution pattern 200, top and lateral surfaces of the line part 200L, and a lateral surface and a portion of a top surface of the pad part 200P. The second polymer dielectric layer 320 may include a photo-imageable polymer material the same as or similar to that of the first polymer dielectric layer 310. The second polymer dielectric layer 320 may include a buffer polymer pattern 320D and a cover polymer pattern 320C. The buffer polymer pattern 320D may have an annular shape as shown in FIGS. 2A and 2C.

The second polymer dielectric layer 320 may include a main via hole MVH defined as a space in an inner circle of the buffer polymer pattern 320D shaped like an annulus, and may also include a subordinate via hole SVH defined as a space between the buffer polymer pattern 320D and the cover polymer pattern 320C. The main via hole MVH may vertically overlap the pad hole 200H of the pad part 200P of the redistribution pattern 200 and may expose the top surface of the first polymer dielectric layer 310. The main via hole MVH may have a circular spatial shape when viewed in plan. The subordinate via hole SVH may expose an edge of the pad part 200P of the redistribution pattern 200. When viewed in plan, the subordinate via hole SVH may have an annular shape that surrounds the main via hole MVH.

The buffer polymer pattern 320D may be spaced apart from without being connected to the cover polymer pattern 320C.

The under-bump pattern 400 may be disposed on the buffer polymer pattern 320D and the redistribution pattern 200. The under-bump pattern 400 may include a second seed/barrier pattern 410 and a second conductive pattern 420. The second conductive pattern 420 may be disposed on the second seed/barrier pattern 410. The second seed/barrier pattern 410 may include a material substantially the same as or similar to that of the first seed/barrier pattern 210, and the second conductive pattern 420 may include a material substantially the same as or similar to that of the first conductive pattern 220. The under-bump pattern 400 may further include a metal pattern, including one or more of nickel and gold, disposed on the second conductive pattern 420. The metal pattern may improve wettability between the connection terminal 500 and the under-bump pattern 400, or may prevent undesirable diffusion between the connection terminal 500 and the under-bump pattern 400.

The under-bump pattern 400 may include a main via 400M, a connection part 400C, and a subordinate via 400S. The main via 400M may fill at least a portion of each of the main via hole MVH and the pad hole 200H. The main via 400M may be in contact with an inner lateral surface S1 (which constitutes the main via hole MVH) of the buffer polymer pattern 320D and an inner lateral surface (which constitutes the pad hole 200H) of the pad part 200P. The second seed/barrier pattern 410 of the main via 400M may be in contact with the first seed/barrier pattern 210 and the first conductive pattern 220 of the redistribution pattern 200. According to some implementations, the second seed/barrier pattern 410 may not be in contact with the first seed/barrier pattern 210.

The subordinate via 400S may be in contact with an outer lateral surface S2 (which constitutes the subordinate via hole SVH) of the buffer polymer pattern 320D and an inner lateral surface S3 (which constitutes the subordinate via hole SVH) of the cover polymer pattern 320C. The subordinate via 400S may be in contact with the top surface of the pad part 200P. The connection part 400C may be disposed on the buffer polymer pattern 320D, and may connect the main via 400M and the subordinate via 400S to each other.

As shown in FIGS. 2A and 2C, the main via 400M may have a first width X1 in the first direction D1, and the subordinate via 400S may have a second width X2 in the first direction D1. The first width X1 may correspond to a diameter of the main via hole MVH. The second width X2 may correspond to a diameter of the subordinate via hole SVH. The first width X1 may be greater than at least twice the second width X2. As illustrated in FIG. 2A, the main via 400M may have a first depth H1 in the third direction D3, and the subordinate via 400S may have a second depth H2 in the third direction D3. The first depth H1 may correspond to a distance from a top surface of the buffer polymer pattern 320D to the top surface of the first polymer dielectric layer 310. The second depth H2 may correspond to a distance from the top surface of the buffer polymer pattern 320D to the top surface of the pad part 200P of the redistribution pattern 200. The first depth H1 may be greater than the second depth H2. A lowermost surface of the main via 400M may be located at a lower level than that of a lowermost surface of the subordinate via 400S.

The buffer polymer pattern 320D may be interposed and isolated between the redistribution pattern 200 and the under-bump pattern 400. For example, the buffer polymer pattern 320D may be disposed in a space constituted by the top surface of the pad part 200P of the redistribution pattern 200, an outer lateral surface of the main via 400M, and an inner lateral surface of the subordinate via 400S.

The connection terminal 500 may be disposed on the under-bump pattern 400. The connection terminal 500 may include a conductive material, such as solder. The connection terminal 500 may be shaped like a solder bump or a solder ball.

According to some implementations, as illustrated in FIG. 2D, a recess 400G may be disposed on an upper portion of the subordinate via 400S.

When a redistribution pattern has a thickness of equal to or greater than about 10 μm, a resistance may decrease to improve efficiency of power that flows through the redistribution pattern. However, an increase in thickness of the redistribution pattern may induce an increase in sum of a thickness of an under-bump pattern and a thickness of a pad part of the redistribution pattern and an increase in distance from a connection terminal of the under-bump pattern to a thickness center of the pad part, which may result in an increase in electrical path length. As a result, in consideration of overall performance of a semiconductor package, it may be required that the redistribution pattern have a thickness of less than about 10 μm. According to the present disclosure, the pad part 200P of the redistribution pattern 200 may include the pad hole 200H, and the under-bump pattern 400 may fill the pad hole 200H. A portion of the under-bump pattern 400 may serve as a pad of the redistribution pattern 200, and thus there may be a reduction in distance from the connection terminal 500 to a thickness center of the redistribution pattern 200. As a result, an electrical path length may decrease while utilizing an advantage of increase in thickness of the redistribution pattern 200. In addition, the subordinate via 400S of the under-bump pattern 400 may distribute stress concentrated on an edge of the under-bump pattern 400, and may be connected to the pad part 200P of the redistribution pattern 200, which may result in an increase in reliability of electrical connection. The buffer polymer pattern 320D may be interposed between the main via 400M and the subordinate via 400S and between the under-bump pattern 400 and the redistribution pattern 200 to thereby attenuate stress occurring due to a difference in coefficient of thermal expansion (CTE) between the second polymer dielectric layer 320, the under-bump pattern 400, and the redistribution pattern 200.

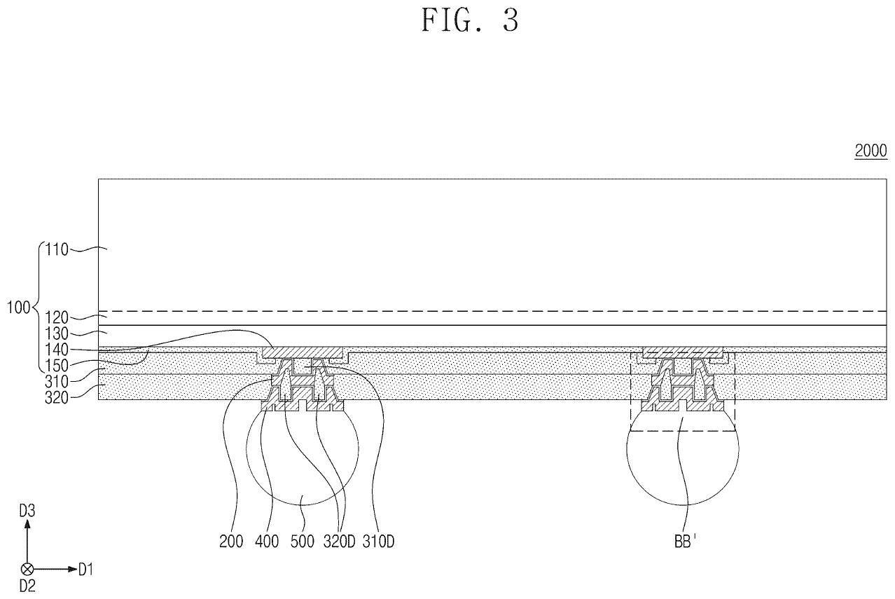

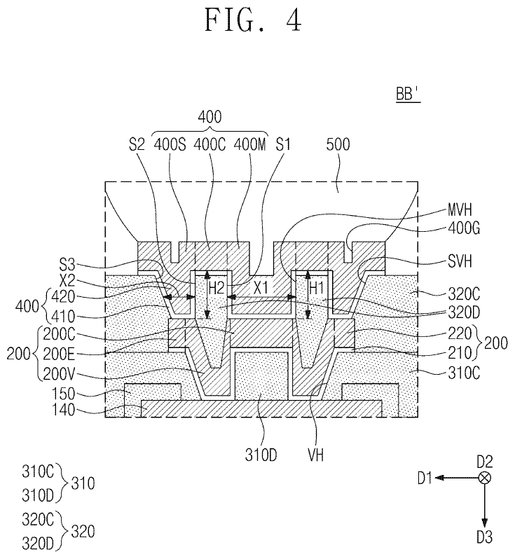

FIG. 3 illustrates a cross-sectional view showing an example of a semiconductor package. FIG. 4 illustrates an example enlarged view showing section BB′ of FIG. 3. Omission will be made to avoid duplicate explanation in FIG. 1.

Referring to FIGS. 3 and 4, the first polymer dielectric layer 310 may include a first buffer polymer pattern 310D and a first cover polymer pattern 310C. The first polymer dielectric layer 310 except the first buffer polymer pattern 310D may be called the first cover polymer pattern 310C. The first buffer polymer pattern 310D may have, for example, a cylindrical shape (or a circular column shape). The first polymer dielectric layer 310 may include a via hole VH having an annular spatial shape. The via hole VH may be defined to refer to a space between the first buffer polymer pattern 310D and the first cover polymer pattern 310C.

The redistribution pattern 200 may include an extension part 200E connected to one end of the via part 200V, and may also include a connection part 200C connected to another end of the via part 200V. The extension part 200E may be disposed on a top surface of the first cover polymer pattern 310C. The connection part 200C may be disposed on the first buffer polymer pattern 310D. The via part 200V may fill at least a portion of the via hole VH.

The second polymer dielectric layer 320 may be disposed on the redistribution pattern 200 and the first polymer dielectric layer 310. The second polymer dielectric layer 320 may include a second cover polymer pattern 320C and a second buffer polymer pattern 320D. The main via hole MVH may overlap in the third direction D3 with the first buffer polymer pattern 310D and the connection part 200C of the redistribution pattern 200. The subordinate via hole SVH may overlap in the third direction D3 with the extension part 200E of the redistribution pattern 200.

The under-bump pattern 400 may fill at least a portion of each of the main via hole MVH and the subordinate via hole SVH, and may extend onto the second buffer polymer pattern 320D.

The main via 400M may fill at least a portion of the main via hole MVH. The main via 400M may be in contact with an inner lateral surface S1 (which constitutes the main via hole MVH) of the second buffer polymer pattern 320D. A bottom surface of the main via 400M may be in contact with a top surface of the connection part 200C of the redistribution pattern 200. The connection part 200C may serve as a pad in contact with the main via 400M. The second seed/barrier pattern 410 of the main via 400M may be in contact with the redistribution pattern 200 and the first conductive pattern 220.

The subordinate via 400S may be in contact with an outer lateral surface S2 (which constitutes the subordinate via hole SVH) of the second buffer polymer pattern 320D and an inner lateral surface S3 (which constitutes the subordinate via hole SVH) of the second cover polymer pattern 320C. The subordinate via 400S may be in contact with a top surface of the extension part 200E. The extension part 200E may serve as a pad in contact with the subordinate via 400S. The under-bump pattern 400 and the redistribution pattern 200 may have a stacked via structure. When the redistribution pattern 200 has a stacked via structure, the redistribution pattern 200 may have a thickness either of equal to or less than about 10 μm or of equal to or greater than about 10 μm.

The main via 400M may have a first width X1 in the first direction D1, and the subordinate via 400S may have a second width X2 in the first direction D1. The first width X1 may correspond to a diameter of the main via hole MVH. The second width X2 may correspond to a diameter of the subordinate via hole SVH. The first width X1 may be greater than at least twice the second width X2. As illustrated in FIG. 2A, the main via 400M may have a first depth H1 in the third direction D3, and the subordinate via 400S may have a second depth H2 in the third direction D3. The firth depth H1 may correspond to a distance from a top surface of the second buffer polymer pattern 320D to the top surface of the pad part 200P of the redistribution pattern 200. The second depth H2 may correspond to a distance from the top surface of the second buffer polymer pattern 320D to the top surface of the extension part 200E of the redistribution pattern 200. The first depth H1 and the second depth H2 may be substantially the same as each other.

As a stacked via structure does not require a line part of a redistribution pattern, there may be a length reduction in electrical path (e.g., a path through which current flows) and an improvement in power efficiency. However, when an under-bump pattern is in direct contact with the redistribution pattern and the redistribution whose size corresponds to that of a pad are in direct contact with each other without any of a first buffer polymer pattern, a second buffer polymer pattern, and a subordinate via, a junction part between the under-bump pattern and the redistribution pattern may suffer from cracks occurring due to stress, and a second buffer polymer dielectric layer may be undesirably inserted between the redistribution pattern and the under-bump pattern.

According to the present disclosure, the first buffer polymer pattern 310D and the second buffer polymer pattern 320D may serve as a buffer to attenuate stress. The subordinate via 400S may also reduce stress. For example, cracks may be prevented from occurring between the under-bump pattern 400 and the redistribution pattern 200 while increasing power efficiency, and thus the semiconductor package 2000 may improve in reliability.

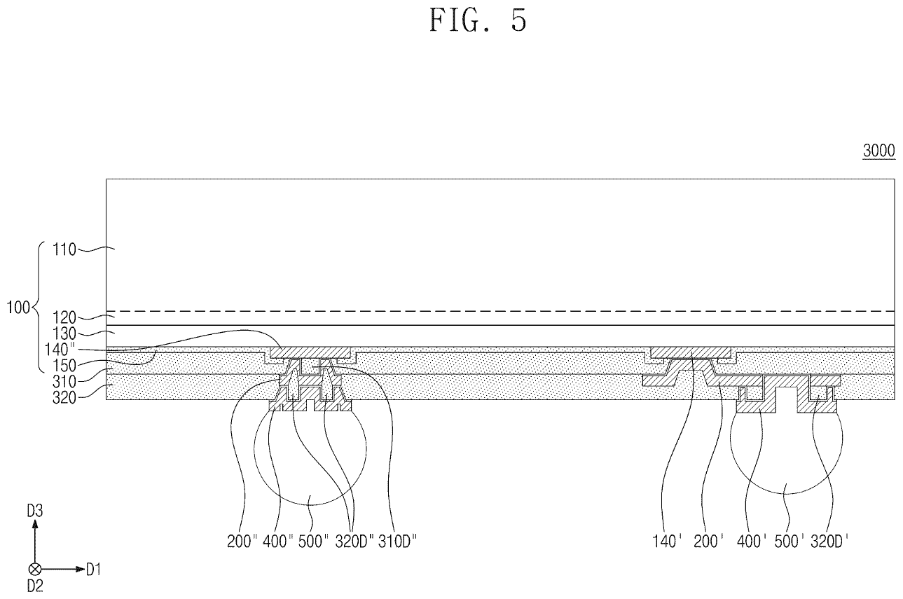

FIG. 5 illustrates a cross-sectional view showing an example of a semiconductor package. Omission will be made to avoid duplicate explanation in FIGS. 1 to 3.

A semiconductor package 3000 according to some implementations may include characteristics of the semiconductor package 1000 of FIG. 1 and characteristics of the semiconductor package 2000 of FIG. 3. For example, one of the chip pads 140 may be connected to a redistribution pattern 200′ including a via part, a line part, and a pad part that has a pad hole. An under-bump pattern 400′ may include a main via that fills the pad hole and a subordinate via that connects with the pad part. A buffer polymer pattern 320D′ may be interposed between the main via and the subordinate via. A connection terminal 500′ may be disposed on the under-bump pattern 400′.

At least one 140″ of the remainder of the chip pads 140 may be connected to a redistribution pattern 200″ and an under-bump pattern 400″ that have a stacked via structure. A via part of the redistribution pattern 200″ and a via part of the under-bump pattern 400″ may all overlap in the third direction D3 with the chip pad 140. A first buffer polymer pattern 310D″ may be interposed between the redistribution pattern 200″ and the chip pad 140″, and a second buffer polymer pattern 320D″ may be interposed between the under-bump pattern 400″ and the redistribution pattern 200″. A connection terminal 500″ may be disposed on the under-bump pattern 400″.

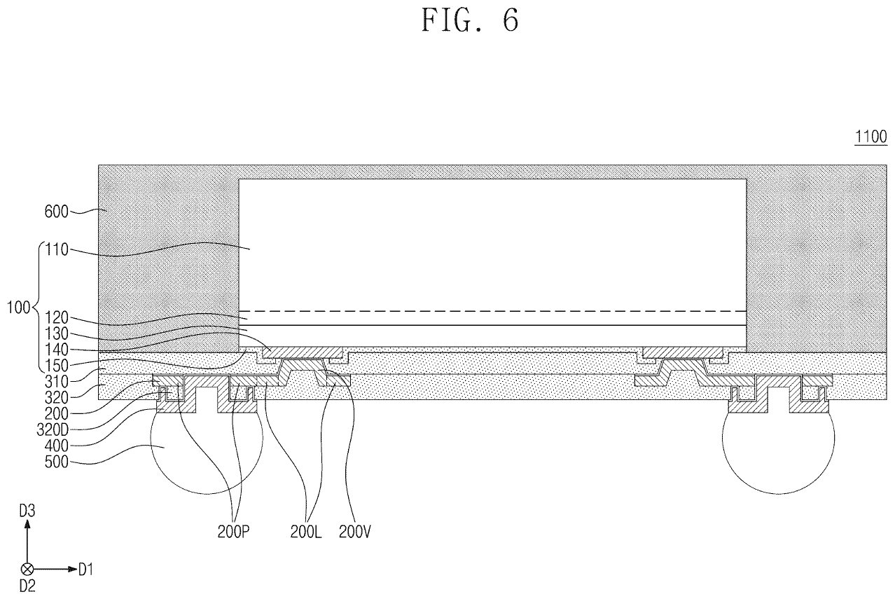

FIG. 6 illustrates a cross-sectional view showing an example of a semiconductor package. Omission will be made to avoid duplicate explanation in FIG. 1.

Referring to FIG. 6, in a semiconductor package 1100 according to some implementations, a width in the first direction D1 of each of the first and second polymer dielectric layers 310 and 320 may be greater than a width in the first direction D1 of the semiconductor chip 100. Likewise, a width in the second direction D2 of each of the first and second polymer dielectric layers 310 and 320 may be greater than a width in the second direction D2 of the semiconductor chip 100. At least a portion of the pad part 200P of the redistribution pattern 200 may not vertically overlap the semiconductor chip 100. At least a portion of the under-bump pattern 400 may not vertically overlap the semiconductor chip 100. At least a portion of the connection terminal 500 may not vertically overlap the semiconductor chip 100. For example, the semiconductor package 1100 may be a fan-out semiconductor package.

As illustrated in FIG. 6, a molding structure 600 may be disposed on a top surface of the first polymer dielectric layer 310. The molding structure 600 may cover the top surface of the first polymer dielectric layer 310 and lateral and top surfaces of the semiconductor chip 100. The molding structure 600 may include an epoxy molding compound (EMC).

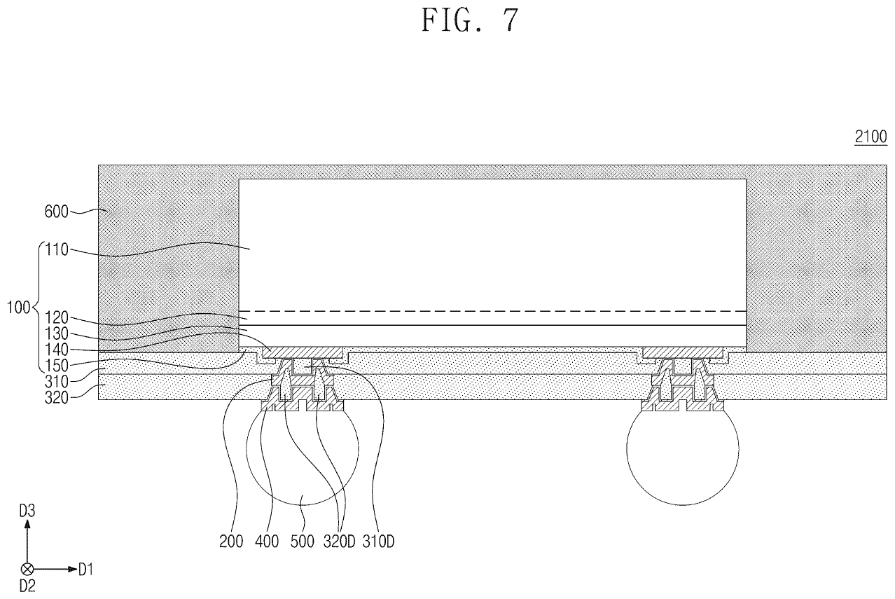

FIG. 7 illustrates a cross-sectional view showing an example of a semiconductor package. Omission will be made to avoid duplicate explanation in FIG. 3.

Referring to FIGS. 3 and 7, in a semiconductor package 2100 according to some implementations, a width in the first direction D1 of each of the first and second polymer dielectric layers 310 and 320 may be greater than a width in the first direction D1 of the semiconductor chip 100. Likewise, a width in the second direction D2 of each of the first and second polymer dielectric layers 310 and 320 may be greater than a width in the second direction D2 of the semiconductor chip 100. As illustrated in FIG. 7, a molding structure 600 may be disposed on a top surface of the first polymer dielectric layer 310, and may cover the top surface of the first polymer dielectric layer 310 and lateral and top surfaces of the semiconductor chip 100.

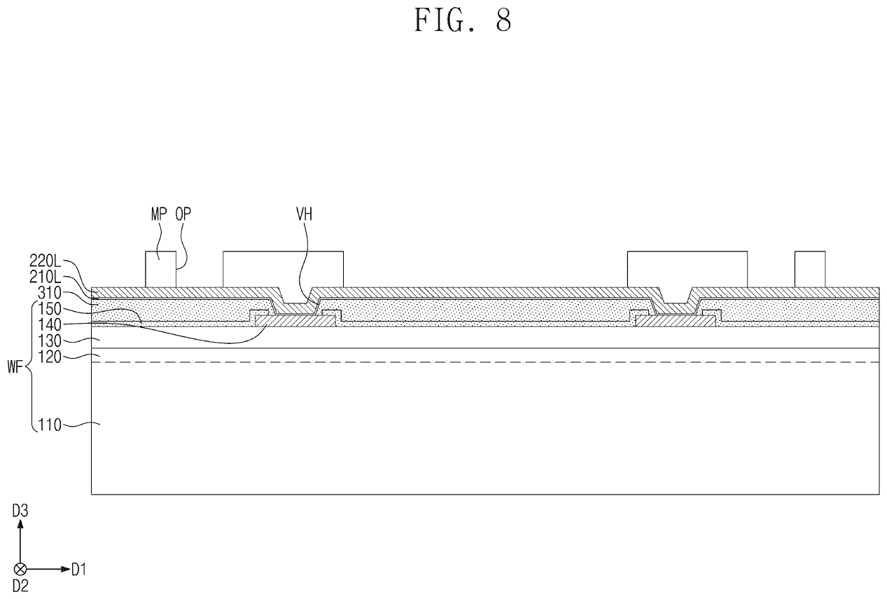

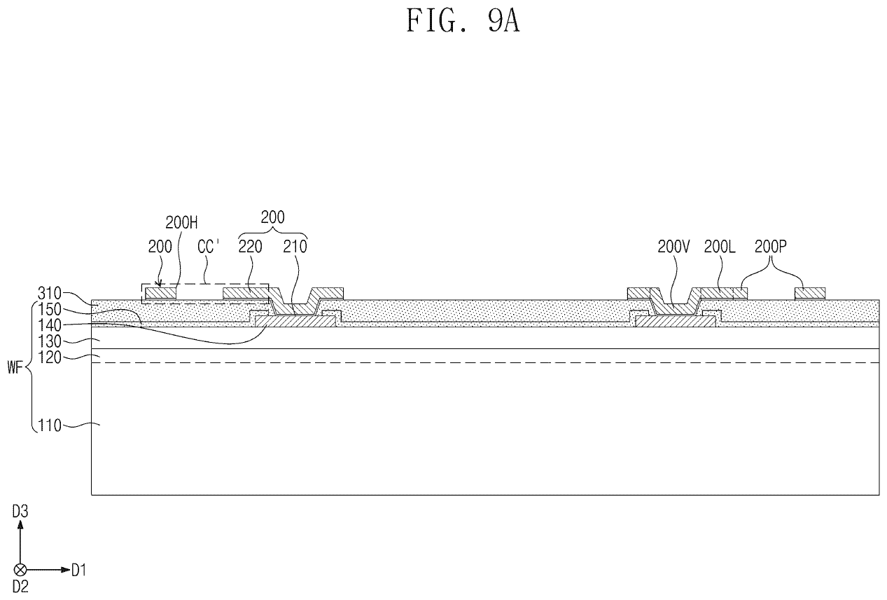

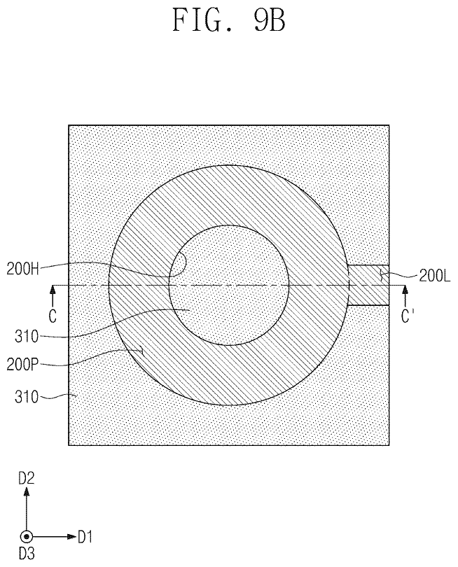

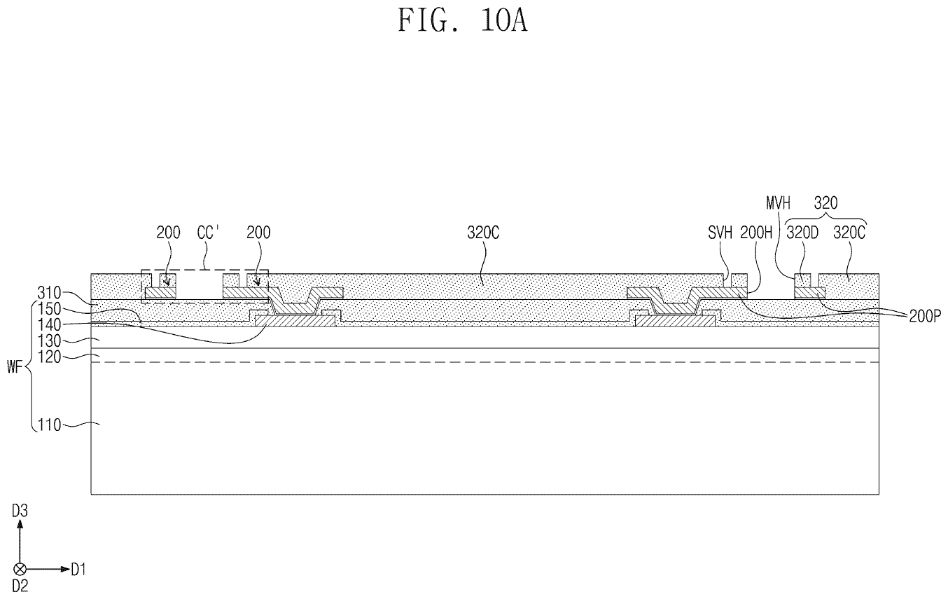

FIGS. 8, 9A, 10A, and 11A illustrate example cross-sectional views showing a method of fabricating a semiconductor package. FIGS. 9B, 10B, and 11B illustrate example plan views showing top surfaces taken along line CC′ of FIGS. 9A, 10A, and 11A, respectively.

Referring to FIG. 8, a wafer WF may be provided to include a semiconductor substrate 110, a circuit layer 120, a wiring layer 130, a chip pad 140, and a protection layer 150.

A first polymer dielectric layer 310 may be formed on the chip pad 140. The formation of the first polymer dielectric layer 310 may include coating a photo-imageable dielectric material on the protection layer 150 and the chip pad 140, employing exposure and development processes to form a via hole VH that exposes the chip pad 140, and performing a curing process.

A seed/barrier layer 210L and a conductive layer 220L may be sequentially formed on a top surface of the first polymer dielectric layer 310. The formation of the seed/barrier layer 210L may be achieved by using one of methods such as physical vapor deposition (PVD), chemical vapor deposition (CVD), and atomic layer deposition (ALD). The seed/barrier layer 210L may be used as an electrode to perform an electroplating process to form the conductive layer 220L.

A mask pattern MP including openings OP may be formed on the conductive layer 220L. The mask pattern MP may be formed by, for example, coating, exposing, and developing a photoresist material. The opening OP may expose a region other than a region where a redistribution pattern will be formed.

Referring to FIGS. 8, 9A, and 9B, the mask pattern MP may be used as an etching mask to sequentially etch the conductive layer 220L and the seed/barrier layer 210L to form a redistribution pattern 200 including a conductive pattern 220 and a seed/barrier pattern 210. In this step, a pad hole 200H may be formed in a pad part 200P of the redistribution pattern 200.

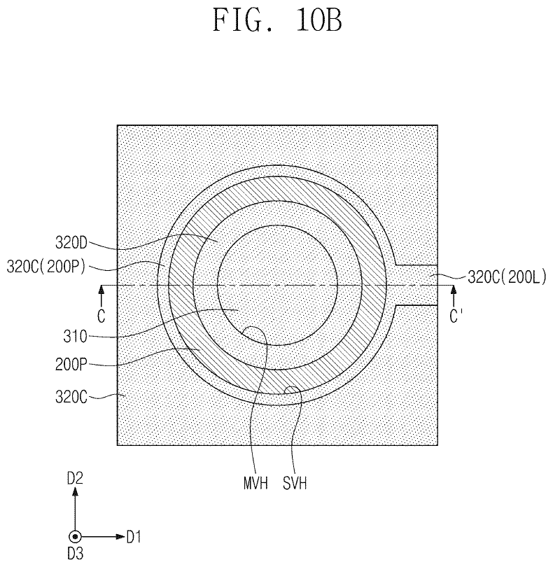

Referring to FIGS. 10A and 10B, a second polymer dielectric layer 320 may be formed on the redistribution pattern 200 and the first polymer dielectric layer 310. The second polymer dielectric layer 320 may include a cover polymer pattern 320C, a buffer polymer pattern 320D, a main via hole MVH, and a subordinate via hole SVH that are formed at the same time. According to some implementations, the cover polymer pattern 320C, the buffer polymer pattern 320D, the main via hole MVH, and the subordinate via hole SVH may be sequentially formed. The formation of the second polymer dielectric layer 320 may include coating a photo-imageable dielectric material on the redistribution pattern 200 and the first polymer dielectric layer 310, performing exposure and development processes to form the main via hole MVH that exposes the chip pad 140 and the subordinate via hole SVH that exposes an edge of the pad part, and performing a curing process.

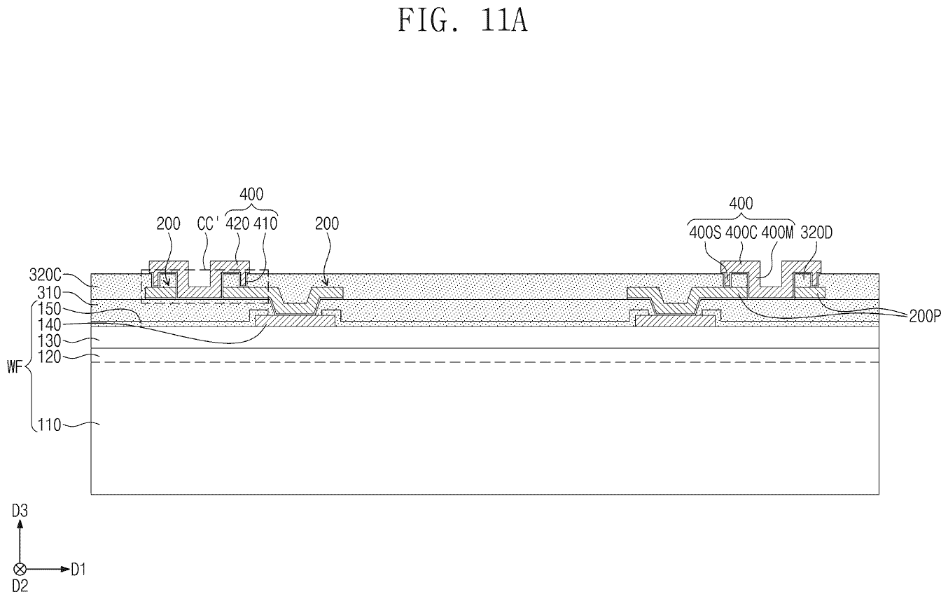

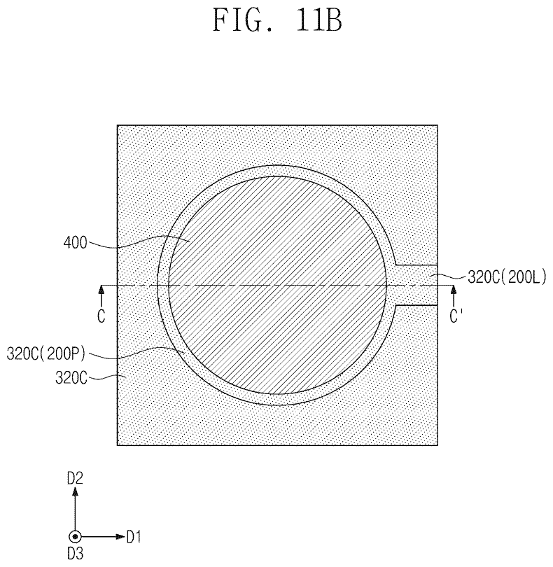

Referring to FIGS. 11A and 11B, an under-bump pattern 400 may be formed by a method similar to that used for forming the redistribution pattern 200. The formation of the under-bump pattern 400 may include forming a seed/barrier layer, performing an electroplating process to form a conductive layer, and performing an etching process that uses a mask pattern to pattern the seed/barrier layer and the conductive layer to form a second seed/barrier pattern 410 and a second conductive pattern 420. The under-bump pattern 400 may fill the pad hole 200H, the main via hole MVH, and the subordinate via hole SVH.

Referring back to FIGS. 1 and 11A, a connection terminal 500 may be formed on the under-bump pattern 400. The wafer WF may be diced to fabricate a semiconductor package 1000.

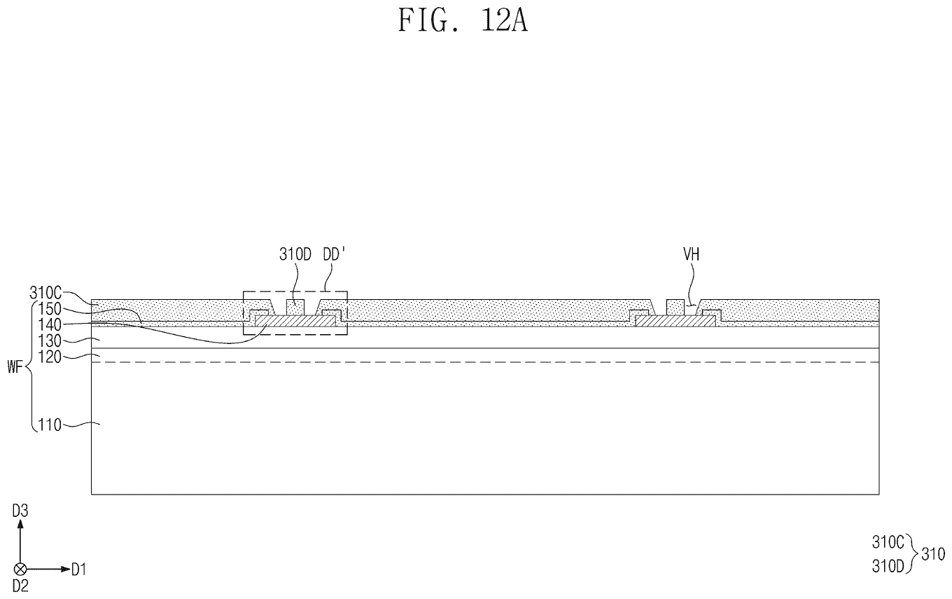

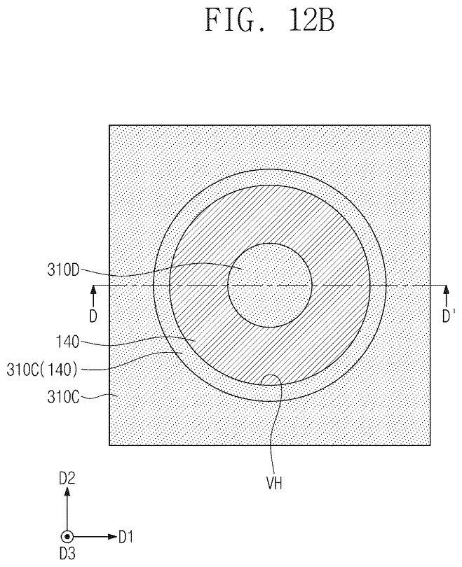

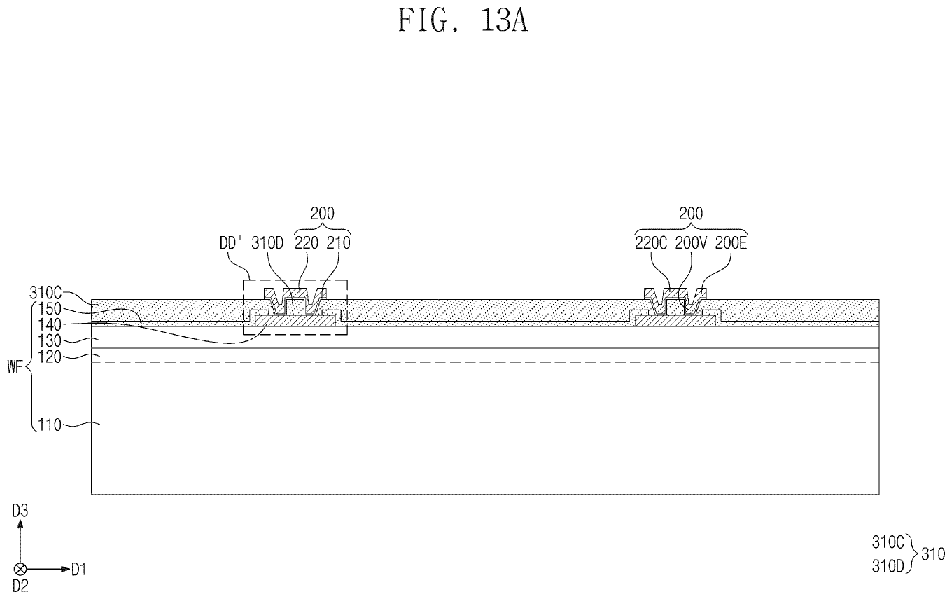

FIGS. 12A, 13A, 14A, and 15A illustrate example cross-sectional views showing a method of fabricating a semiconductor package. FIGS. 12B, 13B, 14B, and 15B illustrate example plan views showing top surfaces taken along line D-D′ of FIGS. 12A, 13A, 14A, and 15A, respectively.

Referring to FIGS. 12A and 12B, a first polymer dielectric layer 310 may be formed on the chip pad 140. The first polymer dielectric layer 310 may include a first buffer polymer pattern 310D and a first cover polymer pattern 310C. The formation of the first buffer polymer pattern 310D and the first cover polymer pattern 310C may include coating a photo-imageable dielectric material on the protection layer 150 and the chip pad 140, employing exposure and development processes to form a via hole VH that exposes the chip pad 140, and performing a curing process.

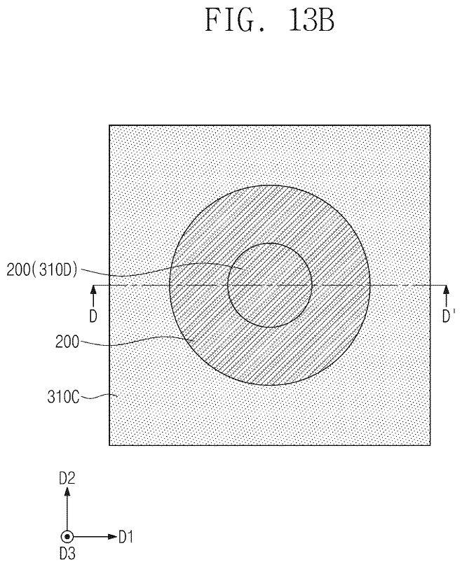

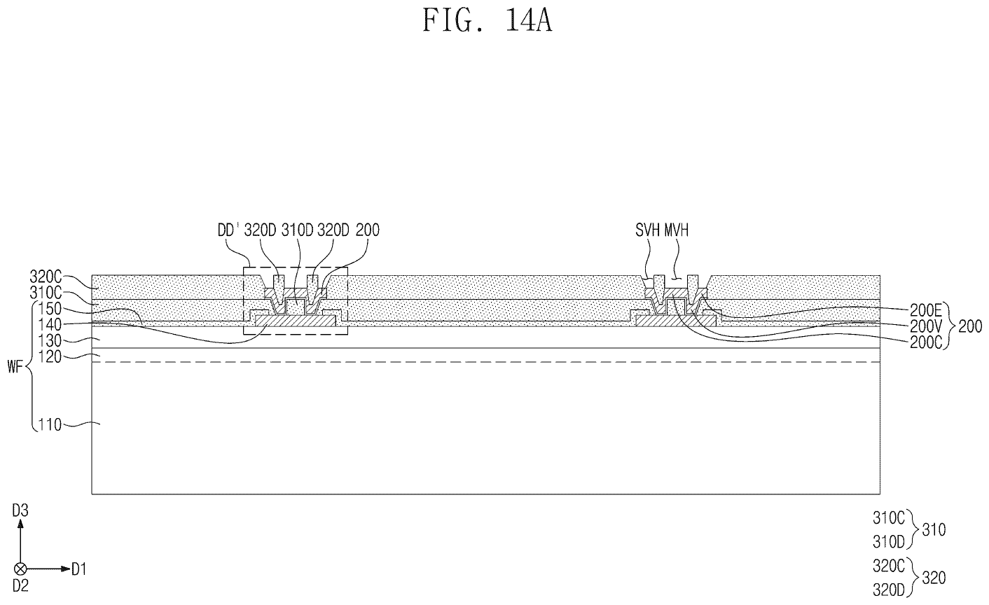

Referring to FIGS. 13A and 13B, a redistribution pattern 200 may be formed to contact the chip pad 140. The formation of the redistribution pattern 200 may include sequentially forming a seed/barrier layer and a conductive layer on the first buffer polymer pattern 310D and the first cover polymer pattern 310C and in the via hole VH, and patterning the seed/barrier layer and the conductive layer to form a first conductive pattern 220 and a first seed/barrier pattern 210.

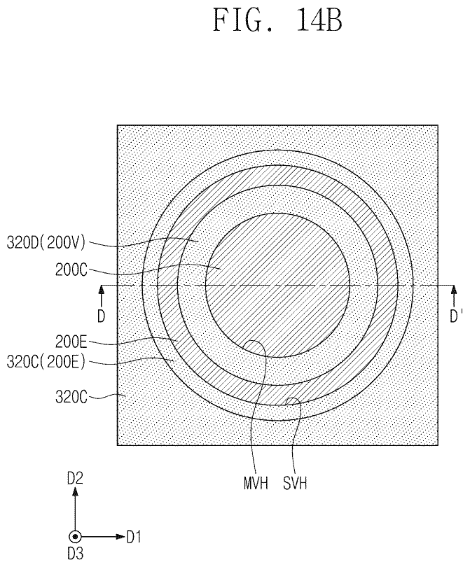

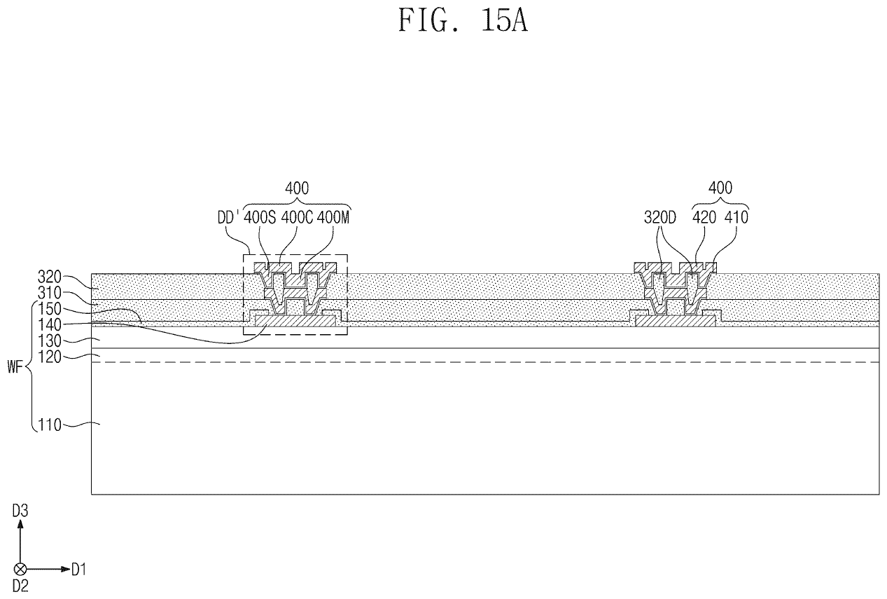

Referring to FIGS. 14A and 14B, a second polymer dielectric layer 320 may be formed on the first polymer dielectric layer 310 and the redistribution pattern 200. The second polymer dielectric layer 320 may include a second buffer polymer pattern 320D and a second cover polymer pattern 320C. The formation of the second buffer polymer pattern 320D and the second cover polymer pattern 320C may include coating a photo-imageable dielectric material on the first polymer dielectric layer 310 and the redistribution pattern 200, and employing exposure and development processes to form a main via hole MVH and a subordinate via hole SVH. The main via hole MVH may expose a top surface of the connection part 200C of the redistribution pattern 200. The subordinate via hole SVH may expose a top surface of the extension part 200E of the redistribution pattern 200.

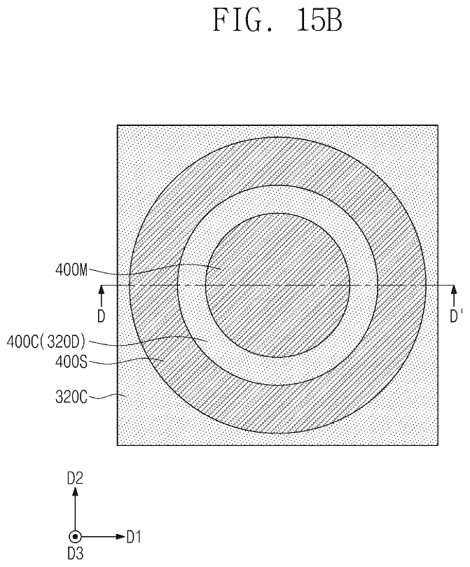

Referring to FIGS. 15A and 15B, an under-bump pattern 400 may be formed by a method similar to that used for forming the redistribution pattern 200. The formation of the under-bump pattern 400 may include forming a seed/barrier layer, performing an electroplating process to form a conductive layer, and performing an etching process that uses a mask pattern to pattern the seed/barrier layer and the conductive layer to form a second conductive pattern 420 and a second seed/barrier pattern 410. The under-bump pattern 400 may fill the main via hole MVH and the subordinate via hole SVH, and may extend onto a top surface of the second buffer polymer pattern 320D. An edge of the under-bump pattern 400 may extend onto a top surface of the second cover polymer pattern 320C.

Referring back to FIGS. 3 and 14A, a connection terminal 500 may be formed on the under-bump pattern 400. The wafer WF may be diced to fabricate a semiconductor package 2000.

According to the present disclosure, a semiconductor package may include a redistribution pattern connected to a chip pad, an under-bump pattern on the redistribution pattern, and a buffer polymer pattern between the under-bump pattern and the redistribution pattern. The under-bump pattern may include a main via at a center thereof and a subordinate via at an edge thereof. The subordinate via may penetrate a polymer dielectric layer to contact the redistribution pattern. The subordinate via and the buffer polymer pattern may attenuate stress concentration on the edge of the under-bump pattern. According to the present disclosure, when an electrical path from the connection terminal to the chip pad passes through the under-bump pattern and the redistribution pattern, a shape of the redistribution pattern may be changed to reduce a length of the electrical path. Accordingly, cracks may be prevented and power efficiency may be increased to improve reliability of the semiconductor package.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

This detailed description of the present disclosure should not be construed as limited to the implementations set forth herein, and it is intended that the present disclosure covers the various combinations, the modifications and variations of this disclosure without departing from the spirit and scope of the present disclosure.

What is claimed is:

1. A semiconductor package, comprising:
a semiconductor chip that includes a chip pad on a first surface of the semiconductor chip;
a redistribution pattern electrically connected with the chip pad;
an under-bump pattern on the redistribution pattern; and
a first buffer polymer pattern between the under-bump pattern and the redistribution pattern,
wherein the under-bump pattern includes a main via and a subordinate via, the main via being at a center of the under-bump pattern, and the subordinate via being at an edge of the under-bump pattern,
wherein the first buffer polymer pattern is between the main via and the subordinate via,
wherein the main via and the subordinate via contact the redistribution pattern, and
wherein the first buffer polymer pattern is isolated by the main via and the subordinate via.

2. The semiconductor package of claim 1, wherein the under-bump pattern includes a connection part that connects the main via and the subordinate via with each other.

3. The semiconductor package of claim 1, comprising a cover polymer pattern that covers the redistribution pattern,
wherein the cover polymer pattern and the first buffer polymer pattern are spaced apart from each other across the subordinate via.

4. The semiconductor package of claim 1, wherein
the main via has a first width in a first direction, the first direction being parallel to the first surface of the semiconductor chip,
the subordinate via has a second width in the first direction, and
the first width is at least twice the second width.

5. The semiconductor package of claim 1, wherein the redistribution pattern has a thickness that is equal to or greater than 10 μm.

6. The semiconductor package of claim 1, wherein the redistribution pattern includes a via part, a line part, and a pad part,
wherein the via part contacts the chip pad,
wherein the line part connects the via part and the pad part with each other,
wherein the pad part defines a pad hole at a central portion of the pad part, the pad hole extending through the pad part, and
wherein the main via is provided at the pad hole.

7. The semiconductor package of claim 6, wherein the main via contacts an inner lateral surface of the redistribution pattern, the inner lateral surface providing the pad hole.

8. The semiconductor package of claim 1, wherein the first buffer polymer pattern includes a photo-imageable dielectric material.

9. The semiconductor package of claim 1, comprising a second buffer polymer pattern between the chip pad and the redistribution pattern.

10. The semiconductor package of claim 9, wherein the main via vertically overlaps the second buffer polymer pattern.

11. The semiconductor package of claim 9, wherein the first buffer polymer pattern has a circular column shape, and the second buffer polymer pattern has an annular column shape.

12. The semiconductor package of claim 9, comprising a cover polymer pattern spaced apart in a first direction from the second buffer polymer pattern, the first direction being parallel to the first surface of the semiconductor chip,
wherein the redistribution pattern includes:
a via part between the cover polymer pattern and the second buffer polymer pattern;
a connection part connected with a first end of the via part and extending onto a top surface of the first buffer polymer pattern; and
an extension part connected with a second end of the via part and extending onto a top surface of the cover polymer pattern.

13. The semiconductor package of claim 12, wherein
the main via contacts the connection part, and
the subordinate via contacts the extension part.

14. The semiconductor package of claim 1, comprising a molding layer that covers a lateral surface of the semiconductor chip,
wherein at least a portion of the under-bump pattern does not vertically overlap the semiconductor chip.

15. The semiconductor package of claim 1, wherein a lowermost surface of the main via is at a level lower than a level of a lowermost surface of the subordinate via.

16. A semiconductor package, comprising:
a semiconductor chip that includes a chip pad on a first surface of the semiconductor chip;
a redistribution pattern electrically connected with the chip pad;
an under-bump pattern contacting the redistribution pattern; and
a connection terminal on the under-bump pattern,
wherein the under-bump pattern includes a main via and a subordinate via, the main via being at a center of the under-bump pattern, and the subordinate via being at an edge of the under-bump pattern,
wherein, in a plan view, the subordinate via has an annular shape that continuously extends to surround the main via,
wherein a horizontal width of the main via is greater than a horizontal width of the subordinate via, and
wherein a depth of the main via is equal to or greater than a depth of the subordinate via.

17. The semiconductor package of claim 16, wherein the redistribution pattern includes a via part, a line part, and a pad part,
wherein the via part contacts the chip pad,
wherein the line part connects the via part and the pad part with each other,
wherein the pad part defines a pad hole at a central portion of the pad part, the pad hole extending through the pad part, and
wherein the main via is provided at the pad hole.

18. The semiconductor package of claim 16, comprising:
a first buffer polymer pattern between the chip pad and the redistribution pattern; and
a second buffer polymer pattern between the under-bump pattern and the redistribution pattern,
wherein the first buffer polymer pattern and the second buffer polymer pattern are spaced apart from each other.

19. The semiconductor package of claim 18, wherein the first buffer polymer pattern and the second buffer polymer pattern include a photo-imageable dielectric material.

20. A semiconductor package, comprising:
a semiconductor chip that includes a chip pad on a first surface of the semiconductor chip;
a protection layer that covers the first surface of the semiconductor chip and exposes the chip pad;
a first cover polymer pattern that covers the protection layer and exposes the chip pad;
a redistribution pattern on the first cover polymer pattern and contacting the chip pad;
a second cover polymer pattern that covers the first cover polymer pattern and the redistribution pattern and that exposes a portion of the redistribution pattern;
an under-bump pattern on the second cover polymer pattern and the redistribution pattern, the under-bump pattern contacting the redistribution pattern;
a buffer polymer pattern between the under-bump pattern and the redistribution pattern; and
a connection terminal on the under-bump pattern,
wherein the protection layer includes an inorganic dielectric material,
wherein each pattern of the redistribution pattern and the under-bump pattern includes a seed/barrier pattern and a conductive pattern on the seed/barrier pattern,
wherein the under-bump pattern includes a main via and a subordinate via, the main via being at a center of the under-bump pattern, and the subordinate via being at an edge of the under-bump pattern,
wherein the buffer polymer pattern is between the main via and the subordinate via, and
wherein the buffer polymer pattern is spaced apart from the first cover polymer pattern and the second cover polymer pattern.
